(19) United States
(12) Patent Application Publication
(10) Pub. No.: US 2023/0197879 A1
(43) Pub. Date: Jun. 22, 2023

(54) GERMANIUM PHOTODIODE WITH REDUCED DARK CURRENT COMPRISING A PERIPHERAL INTERMEDIATE PORTION BASED ON SiGe/Ge

(71) Applicant: Commissariat à l'énergie atomique et aux énergies alternatives, Paris (FR)

(72) Inventors: Abdelkader ALIANE, Grenoble Cedex 09 (FR); Hacile KAYA, Grenoble Cedex 09 (FR); Jean-Michel HARTMANN, Grenoble Cedex 09 (FR)

(73) Assignee: Commissariat à l'énergie atomique et aux énergies alternatives, Paris (FR)

(21) Appl. No.: 18/056,438

(22) Filed: Nov. 17, 2022

(30) Foreign Application Priority Data
Nov. 17, 2021 (FR) 21 12166

(51) Int. Cl. H01L 31/109; H01L 31/028; H01L 31/0312; H01L 31/0336; H01L 31/18

(52) U.S. Cl. CPC H01L 31/109; H01L 31/028; H01L 31/0312; H01L 31/0336; H01L 31/1804; H01L 31/1864

(57) ABSTRACT

A planar photodiode including a main layer including an n-doped first region, a p-doped second region, and an intermediate region, and also a p-doped peripheral lateral portion. It also includes a peripheral intermediate portion, made of an alternation of monocrystalline thin layers of silicon-germanium and germanium, located on the first face, and extending between and at a non-zero distance from the doped first region and from the peripheral lateral portion so as to surround the doped first region in a main plane.

### TECHNICAL FIELD

The field of the invention is that of planar photodiodes based on germanium. The invention is applicable in particular in the field of detecting light radiation in the near infrared.

### PRIOR ART

Optoelectronic photodetection devices may comprise a matrix-array of passivated planar photodiodes. The photodiodes are formed from one and the same germanium-based semiconductor layer, which extends along a main plane, and has two faces that are opposite and parallel to one another. They then each comprise a detection portion, formed for example of a first region made of n+-doped germanium and flush with the first face, a second region made of p+-doped germanium and flush with the second face, and an intermediate region made of intrinsic or very weakly p-doped germanium, and located between the doped first and second regions. A passivation layer made of a dielectric material may cover the first face for the purpose of limiting the contribution of dark current to the electric current measured by each photodiode.

The n+-doped first region and the p+-doped second region may be electrically biased from the side of the first face. A peripheral lateral portion, for example made of p+-doped polycrystalline silicon, thus surrounds the detection portion in a main plane of the photodiode and comes into contact with the p+-doped second region. Metal contacts, arranged on the side of the first face, may come into contact with the n+-doped first region and the p+-doped peripheral lateral portion, and make it possible to reverse-bias the photodiode.

The n+-doped first region may be produced by locally doping the germanium of the detection portion, for example through ion implantation of n-type dopants such as phosphorus, arsenic or antimony. It is then generally necessary to carry out annealing in order to at least partially rectify crystalline defects generated in the germanium by the ion implantation. However, it is apparent that these crystalline defects remain difficult to rectify, in spite of high-temperature annealing. In addition, the annealing operations performed in the fabrication process, such as this high-temperature annealing, may lead to significant and uncontrolled diffusion of these dopants from the diffusion portion. This diffusion of n-type dopants increases the risk of short-circuiting of the photodiode through the formation of pierced zones connecting for example the n+-doped first region and the p+-doped peripheral lateral portion. In addition, these crystalline defects generated by the ion implantation, such as this significant diffusion of n-type dopants, contribute to increasing dark current and therefore to worsening the performance of the photodiode. There is therefore a need to provide a planar photodiode in which dark current is reduced, in particular with regard to the portion of dark current linked to the production of the n+-doped first region.

Documents US 2020/176503 A1, US 2020/168758 A1, US 2021/104644 A1, US 2021/111205 A1, along with the scientific article by Benedikovic et al. entitled Silicon-germanium receivers for short-wave-infrared optoelectronics and communications, Nanophotonics, 2021, 10(3), 1059-1079, describe various examples of planar photodiodes based on germanium.

### DISCLOSURE OF THE INVENTION

The invention aims to at least partially rectify the drawbacks of the prior art, and more particularly to propose a planar photodiode having reduced dark current, in particular the surface component thereof on the first face of the photodiode.

To this end, the subject of the invention is a planar photodiode comprising a main layer having a first face and a second face that are opposite one another and parallel to a main plane, made of a first crystalline semiconductor material based on germanium, comprising a detection portion formed of: an n-type doped first region flush with the first face, intended to be electrically biased; a p-type doped second region flush with the second face; an intermediate region, located between the doped first region and the doped second region and surrounding the doped first region in the main plane. The planar photodiode also comprises a peripheral lateral portion, made of a p-type doped second semiconductor material, surrounding the detection portion in the main plane, and coming into contact with the doped second region, and intended to be electrically biased.

According to the invention, the planar photodiode comprises a peripheral intermediate portion, made of an alternation of monocrystalline thin layers of silicon-germanium and germanium, located in contact with the detection portion on the first face, and extending between and at a non-zero distance from the doped first region and from the peripheral lateral portion so as to surround the doped first region in the main plane.

Some preferred but non-limiting aspects of this photodiode are as follows.

The monocrystalline thin layers of silicon-germanium may comprise an atomic proportion of silicon at least equal to 70%.

The monocrystalline thin layers of silicon-germanium and germanium may each have a thickness less than or equal to 4 nm.

The peripheral intermediate portion may extend into a notch, called peripheral intermediate notch, of the detection portion located on the first face.

The planar photodiode may comprise a central portion made of an n-type doped second crystalline semiconductor material, identical to the first crystalline semiconductor material, located in contact with the detection portion on the first face, and contributing to forming the doped first region.

The planar photodiode may comprise an upper insulating layer covering the detection portion on the first face and the peripheral intermediate portion, and laterally surrounding part of the central portion that projects beyond the detection portion.

The planar photodiode may comprise an upper portion located on and in contact with the central portion, made of an n-type doped crystalline semiconductor material.

The planar photodiode may comprise an upper portion located on and in contact with the detection portion, made of an n-type doped crystalline semiconductor material.

The planar photodiode may comprise metal contacts intended to electrically bias the photodiode, including at least one central metal contact electrically biasing the doped first region and at least one lateral metal contact corning into contact with the peripheral lateral portion.

The detection portion may be made of germanium, and the peripheral lateral portion may be based on silicon.

The invention also relates to a process for fabricating at least one planar photodiode according to any one of the preceding features, comprising the following steps:
producing a stack comprising a first sublayer intended to form the second region and a second sublayer intended to form the intermediate region, both covered by an upper insulating layer
producing the peripheral lateral portion through the stack so as to open out onto the first sublayer
producing a peripheral intermediate notch in the detection portion through the upper insulating layer and part of the second sublayer, surrounding a zone intended to form the doped first region
producing the peripheral intermediate portion, in the peripheral intermediate notch, through epitaxy from the second sublayer.

The fabrication process may comprise the following step, following the production of the peripheral intermediate portion:
producing a central notch in the detection portion through the upper insulating layer, surrounded, in the main plane, by the peripheral intermediate portion
producing a central portion made of a second crystalline semiconductor material identical to the first crystalline semiconductor material, in the central notch, through epitaxy from the second sublayer, and n-type doping the central portion during growth, the central portion thus contributing to forming the doped first region.

The central notch may have a depth with respect to a plane passing through the first face at most equal to that of the peripheral intermediate notch.

The fabrication process may comprise the following steps:
producing a central notch in the detection portion through the upper insulating layer and part of the second sublayer, surrounded, in the main plane, by the peripheral intermediate portion;
producing a central portion made of a second crystalline semiconductor material identical to the first crystalline semiconductor material, in the central notch, through epitaxy from the second sublayer, the second crystalline semiconductor material being not intentionally doped;
producing an upper portion on and in contact with the central portion, made of an n-type doped crystalline semiconductor material;
diffusion annealing, such that the dopants contained in the upper portion diffuse through the central portion and into part of the second sublayer so as to contribute to forming the doped first region.

The fabrication process may comprise the following steps:
producing an upper portion on and in contact with the detection portion, made of an n-type doped crystalline semiconductor material;
diffusion annealing, such that the dopants contained in the upper portion diffuse into part of the second sublayer so as to form the doped first region.

### BRIEF DESCRIPTION OF THE DRAWINGS

Other aspects, aims, advantages and features of the invention will become more clearly apparent on reading the following detailed description of preferred embodiments thereof, which description is given by way of non-limiting example and with reference to the appended drawings, in which:

FIGS. 1A and 1B are schematic and partial, cross-sectional and plan views of a planar photodiode according to one embodiment, in which the n+-doped first region is surrounded by a peripheral intermediate portion based on monocrystalline SiGe/Ge;

FIG. 1C is a schematic, sectional view of one example of a peripheral intermediate portion based on monocrystalline SiGe/Ge, as illustrated in FIG. 1A;

FIGS. 2A to 21 illustrate various steps of a process for fabricating a planar photodiode according to the embodiment illustrated in FIG. 1A;

FIGS. 3A and 3B are schematic and partial, cross-sectional views of a planar photodiode according to some variant embodiments.

### DETAILED DESCRIPTION OF PARTICULAR EMBODIMENTS

In the figures and in the remainder of the description, the same references have been used to designate identical or similar elements. In addition, the various elements are not shown to scale for the sake of clarity of the figures. Moreover, the various embodiments and variants are not mutually exclusive and may be combined with one another. Unless indicated otherwise, the terms “substantially”, “around” and “of” the order of mean to within 10%, and preferably to within 5%. Moreover, the terms “between . . . and . . . ” and the like mean inclusive of limits, unless indicated otherwise.

The invention relates in general to a planar photodiode, and preferably to a matrix-array of photodiodes, and to a process for fabricating such a photodiode. Each photodiode comprises a detection portion based on germanium and is designed to detect light radiation in the near infrared (SWIR, for Short Wavelength IR) corresponding to the spectral range from 0.8 μm to around 1.7 μm, or even to around 2.5 μm.

Each detection portion of the photodiodes is formed in one and the same main semiconductor layer. The latter extends in a main plane, and has a first face and a second face that are opposite to one another and parallel to the main plane. The two faces therefore extend along identical planes for each of the photodiodes, and vertically define (along the thickness axis) the detection portion.

The photodiodes do not have a mesa structure, insofar as they are produced from the same main semiconductor layer and are optically isolated from one another by peripheral lateral trenches filled with a doped semiconductor material. They thus have a particularly high fill factor. Moreover, they are said to be passivated insofar as the surface of the first face is at least partially covered by a passivation dielectric layer. This contributes to reducing the surface component of dark current.

Dark current of a photodiode is the electric current present within the photodiode during operation, when it is not subjected to light radiation. It may be formed of thermally generated currents within the volume of the detection portion (diffusion currents, depletion currents, tunnel currents, etc.) and of surface currents. The surface currents may be linked to the presence of electrical charges in the passivation dielectric layer. Specifically, these electrical charges may induce a modification of the curvature of the energy bands close to the surface, leading to the formation of a depleted zone or of an inversion zone. The depleted zone, when it is located in the space charge zone of the photodiode, may give rise to parasitic generation-recombination currents. Moreover, the inversion zone, which is then electrically conductive, may allow electrical charges to move between n-doped and p-doped biased regions located at the interface with the passivation layer.

Within the scope of the invention, the planar photodiode comprises at least:
a detection portion, formed in a main semiconductor layer made of a first crystalline semiconductor material based on germanium, and comprising: an n-type doped first region, a p-type doped second region, and an intermediate region located between the two doped regions and surrounding the n-type doped first region in the main plane of the photodiode;
a peripheral lateral portion, made of a p-type doped second semiconductor material, surrounding the detection portion in the main plane, and coming into contact with the p-type doped second region, and intended to be electrically biased;
a peripheral intermediate portion, made of an alternation of monocrystalline thin layers of silicon-germanium and germanium, surrounding the n-type doped first region in the main plane, on the first face, and located between and at a non-zero distance from the n-type doped first region and from the p-type doped peripheral lateral portion.

Thus, as described in detail further below, the peripheral intermediate portion formed of an alternation of monocrystalline thin layers of SiGe and Ge contribute to limiting the uncontrolled lateral diffusion of dopants from the n+-doped first region in the direction of the p+-doped peripheral lateral portion, and thus to reducing the surface component of dark current.

Moreover, preferably, the n+-doped first region is produced from an n+-doped central portion made of the first crystalline semiconductor material based on germanium, grown epitaxially from a notch formed in the detection portion from the first face, and doped during growth (that is to say in situ) and not through ion implantation. This thus reduces the number of structural defects in the epitaxially grown material of the central portion compared with the situation in which the doping might be carried out through ion implantation. This thus avoids having to resort to annealing to rectify structural defects, which would lead to a significant and uncontrolled diffusion of dopants from the n+-doped first region. This again reduces the surface component of dark current.

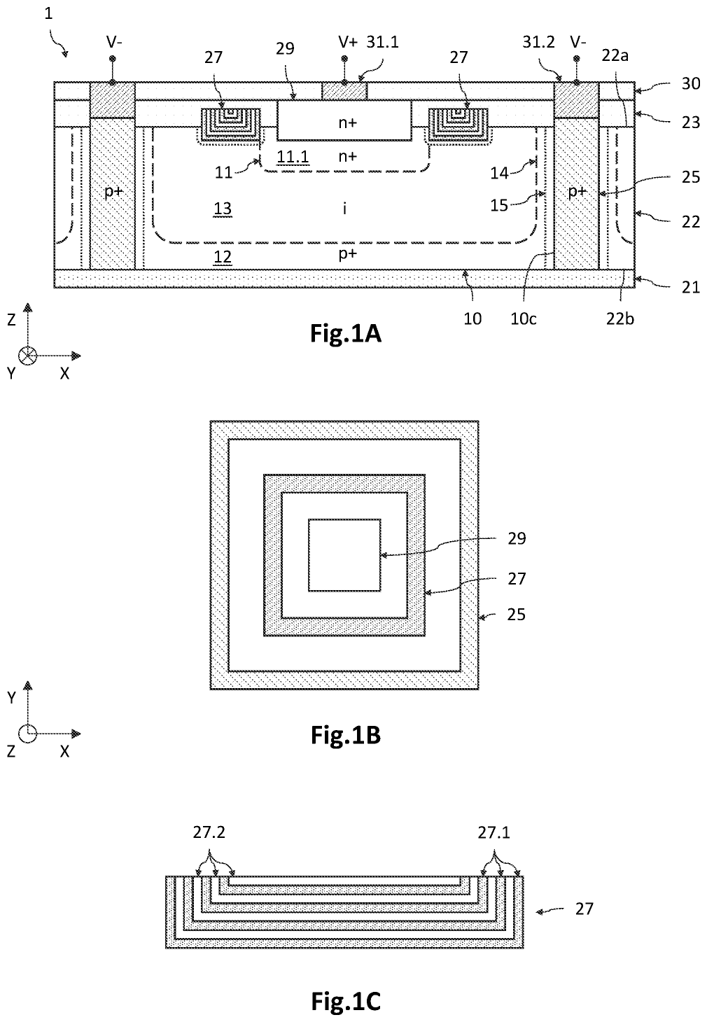

FIGS. 1A and 1B are partial and schematic, sectional and plan views of a planar photodiode 1 according to one embodiment, belonging to a matrix-array of identical planar photodiodes. In addition, FIG. 1C is a schematic, sectional view of one example of a peripheral intermediate portion 27 based on monocrystalline SiGe and Ge.

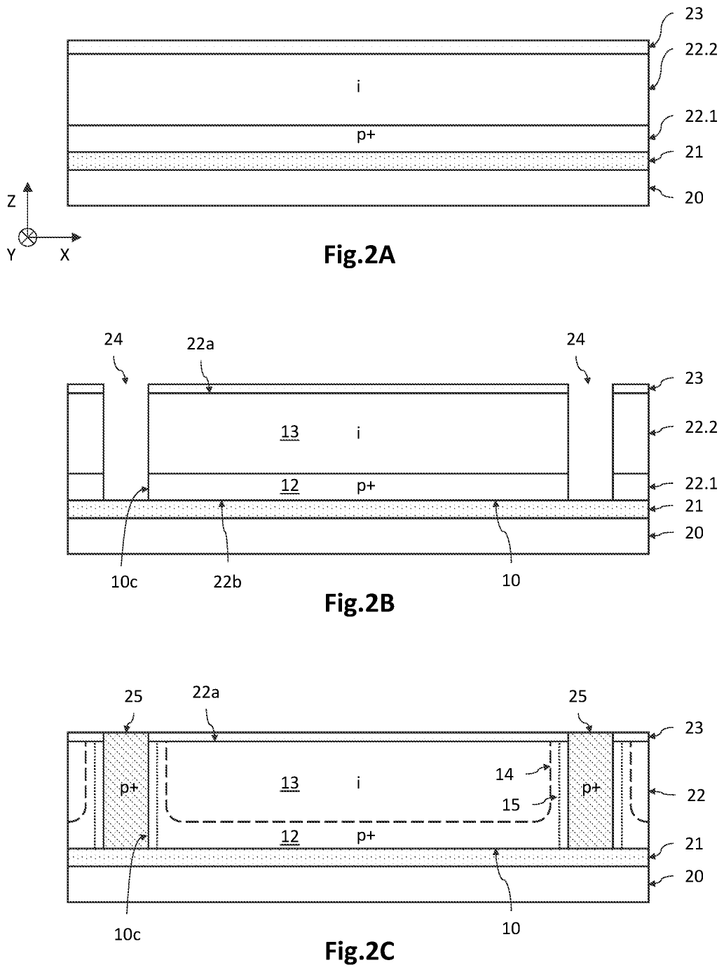

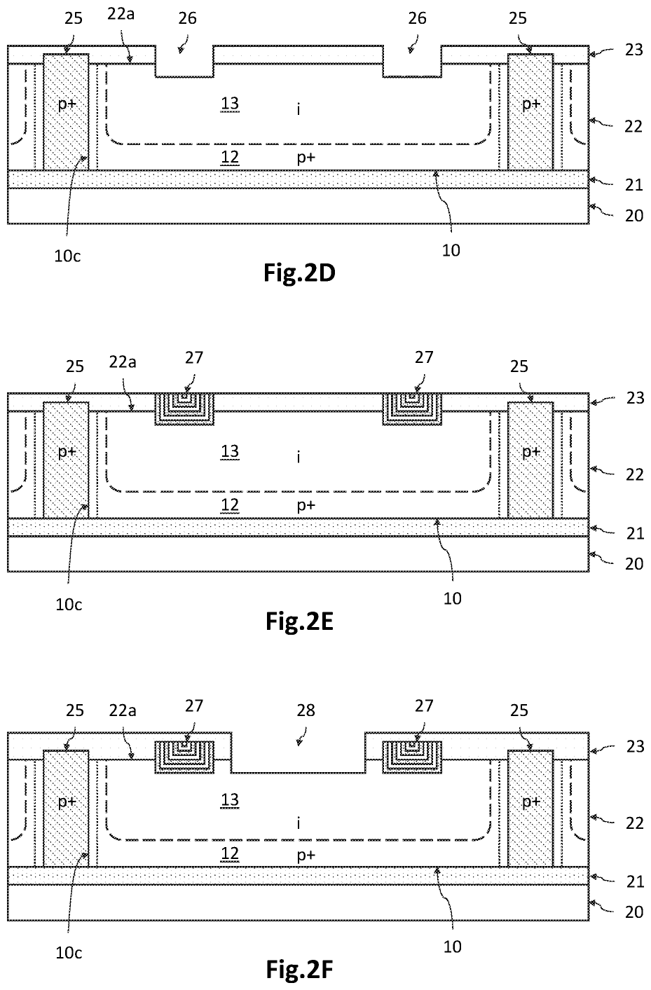

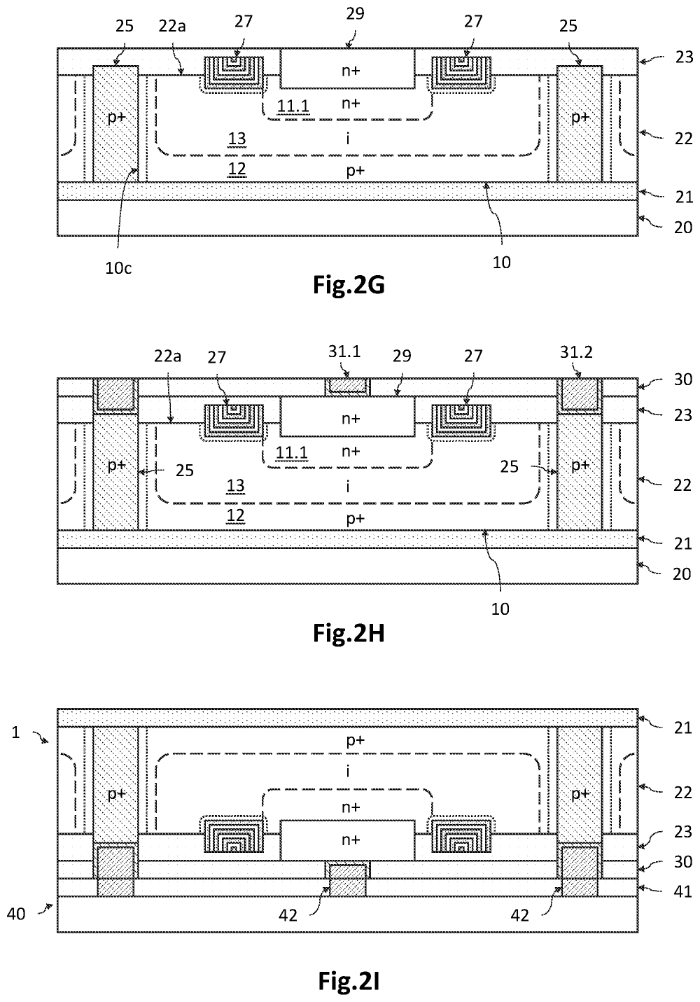

The photodiodes 1 are based on germanium, and are reverse-biased from the first face 22a, while being isolated from one another by peripheral lateral trenches 24 filled with a p+-doped semiconductor material 25 (cf. FIGS. 2B and 2C). They each comprise a peripheral intermediate portion 27 surrounding the n+-doped first region 11 on the first face 22a, and located between and at a distance from the n+-doped first region 11 and the p+-doped peripheral lateral portion 25.

Moreover, in this embodiment, the n+-doped first region 11 is advantageously formed in particular of a central portion 29 made of germanium grown epitaxially from a central notch 28 formed in the detection portion 10 made of germanium (cf. FIG. 2F), and n+-doped during growth.

A three-dimensional direct reference frame XYZ is defined here and for the remainder of the description, in which the X and Y axes form a plane parallel to the main plane of the photodiode 1, and in which the Z axis is oriented along the thickness of the detection portion 10 of the photodiode 1, from the second face 22b in the direction of the first face 22a.

The photodiode 1 comprises what is called a detection portion 10 of the main layer 22, extending along the Z axis between a first and a second face 22a and 22b, which are parallel to one another and opposite one another. The first faces 22a of the photodiodes are coplanar with one another, and the second faces 22b are also coplanar with one another. The first face 22a is defined by part of the detection portion 10 with which the intermediate region 13 is flush. The second face 22b is opposite the first face 22a along the Z axis.

The maximum thickness of the detection portion 10, defined along the Z axis between the first and second faces 22a, 22b, is here substantially constant from one photodiode 1 to the next; for example, it is between a few hundred nanometres and several microns, for example between around 1 μm and 5 μm. The thickness is chosen so as to obtain good absorption in the wavelength range of the light radiation to be detected. The detection portion 10 has a transverse dimension in the XY plane that may be between a few hundred nanometres and a few tens of microns, for example between 1 μm and around 20 μm.

The detection portion 10 is made of a crystalline, preferably monocrystalline, semiconductor material, based on germanium. “Based on germanium” is understood to mean that the crystalline semiconductor material corresponds to germanium or is a compound formed of at least germanium. The photodiodes may thus for example be made of germanium Ge, of silicon-germanium SiGe, of germanium-tin GeSn, or even of silicon-germanium-tin SiGeSn. In this example, the main layer 22 and therefore the detection portion 10 are made of germanium. It may thus be a layer or a substrate made of the same semiconductor material and have regions of various conductivity types (homojunction) so as to form a PN or PIN junction. As a variant, it may be a stack of sublayers of various semiconductor materials (heterojunction), which are then formed based on germanium.

The detection portion 10 is thus formed of an n-type doped first region 11 (here n+-doped), which is flush with the first face 22a and forms an n+-doped well, and a p-type doped second region 12 (here p+-doped), which is flush with the second face 22b. Flush is understood to mean “reach the level of”, or “extends from”. A not intentionally doped intermediate region 13 (in the case of a PIN junction) or a p-doped one (in the case of a PN junction) is located between and in contact with the two doped regions 11 and 12, and surrounds the n+-doped first region 11 in the main plane. In this example, the semiconductor junction is of PIN type, the first region 11 being n+-doped, the second region 12 being p+-doped and the intermediate region 13 is intrinsic (not intentionally doped).

The n+-doped first region 11 extends in this case from the first face 22a and is surrounded by the intrinsic region 13 in the main plane. It is at a distance from the lateral edge 10c of the detection portion 10 in the XY plane, the lateral edge 10c being in contact with the inner face of a p+-doped peripheral lateral portion 25. It thus forms an n+-doped well that is flush with the first face 22a and is spaced by a non-zero distance with respect to the lateral edge 10c and the second face 22b. The n+-doped first region 11 thus contributes to defining the first face 22a. It may exhibit doping that may be between around 5×10¹⁸ and 10²¹ at/cm³.

The p+-doped second region 12 extends in the XY plane flush with the second face 22b, here from the lateral edge 10c. It extends along the Z axis from the second face 22b. It may have a substantially homogeneous thickness along the Z axis and thus be flush only with a lower part of the lateral edge 10c. The p+-doped second region 12 may have a p+-doped lateral region 14 that is continuously flush with the lateral edge 10c along the Z axis and extends over the entire periphery of the detection portion 10. The p+-doped second region 12 may exhibit doping that may be between around 10¹⁸ and 10¹⁹ at/cm³.

The intermediate region 13 is located between the two n+-doped and p+-doped regions 11, 12, and surrounds the n+-doped first region 11 in the XY plane. It is made here of an intrinsic semiconductor material so as to form a PIN junction, but may be weakly p-doped in order to form a PN junction.

The photodiode 1 here comprises a lower insulating layer 21, made of a dielectric material, covering the second face 22b of the detection portion 10 and, as described below, the lower face of the p+-doped peripheral lateral portion 25. The lower insulating layer 21 may furthermore be designed to form an anti-reflection function with regard to the incident light radiation. Specifically, it forms the reception face for the light radiation intended to be detected.

The detection portion 10 of the photodiode 1 is defined laterally here, in the XY plane, by a preferably continuous peripheral lateral trench 24, filled with a p-type doped semiconductor material 25, and forming a peripheral lateral portion 25, which is p+-doped here. The peripheral lateral portion 25 contributes to electrically biasing the photodiode 1, here from the first face 22a, and to pixelating the matrix-array of photodiodes (optical isolation). It extends here across the entire thickness of the detection portion 10 so as to open out onto the lower insulating layer 21, but, as a variant, it might not open out onto the lower insulating layer 21 and may end in the p+-doped second region 12. The inner face of this p+-doped peripheral lateral portion 25 is in contact with the lateral edge 10c of the detection portion 10. The semiconductor material is preferably based on silicon, for example amorphous silicon, polycrystalline silicon, silicon-germanium, or may even be made of amorphous germanium.

An upper insulating layer 23 covers the first face 22a of the photodiode 1, and allows the metal contacts 31.1 and 31.2 to be electrically insulated. It is thus in contact with the n+-doped first region 11 and with the intermediate region 13. It is made of a dielectric material, such as a silicon oxide, a silicon nitride, or a silicon oxynitride. Other dielectric materials may be used, such as a hafnium oxide or aluminium oxide, or even an aluminium nitride, inter alia. It has a thickness of for example between 50 nm and 500 nm.

Moreover, the detection portion 10 advantageously comprises a p-type doped lateral region 14 located at the lateral edge 10c. This lateral region 14 has a doping level higher than that of the intermediate region 13 when it is doped. The p+-doped lateral region 14 is flush with the lateral edge 10c and is in contact with the p+-doped peripheral lateral portion 25. The biasing of the p+-doped second region 12 is thus improved in that the contact surface with the p+-doped peripheral lateral portion 25 is increased. In addition, this p+-doped lateral region 14 makes it possible to avoid the space charge zone of the photodiode 1 extending to the lateral edge 10c. The contribution of this zone (which is potentially not free from defects related to the production of the trenches) to dark current is thus limited. The performance of the photodiode 1 is thus improved.

Moreover, in the case, such as here, of the detection portion 10 being made of germanium, and of the p+-doped peripheral lateral portion 25 being made of silicon, the detection portion 10 then advantageously comprises a lateral zone 15 based on silicon-germanium. The lateral zone 15 is flush with the lateral edge 10c and is in contact with the p+-doped peripheral lateral portion 25. The lateral zone 15 thus has a bandgap (gap) energy greater than that of the detection portion 10 made of germanium. This lateral “gap opening” makes it possible to reduce the sensitivity of the photodiode 1 to defects present near the trenches 24. The performance of the photodiode 1 is thus also improved.

In this embodiment, the n+-doped first region 11 is advantageously formed firstly of a central portion 29 made of germanium grown epitaxially in a central notch 28 formed in the detection portion 10 and n+-doped during growth, and secondly by an n+-doped zone 11.1 adjacent to the central portion 29 and located in the detection portion 10.

The n+-doped central portion 29 is therefore located on and in contact with the detection portion 10 and extends from a plane passing through the first face 22a over a non-zero depth, for example of the order of a few hundred nanometres, for example 200 nm. It also projects here above this plane in the +Z direction, and is laterally surrounded by and in contact with the upper insulating layer 23.

The germanium of the n+-doped central portion 29 is grown epitaxially locally from the surface that has been freed of germanium of the detection portion 10, in the central notch 28. The upper insulating layer 23 therefore forms a growth mask. The fact that the n+-doped central portion 29 is not made of the same material as that of the detection portion 10 means that there is no mismatch in the lattice parameter. The crystalline quality of the n+-doped central portion 29 is therefore very good, thereby reducing dark current. By way of example, the dislocation rate in the n+-doped central portion 29 may be less than 10³ dislocations/cm² in that there is no difference in lattice parameter between the central portion 29 made of n+-doped germanium and the underlying germanium.

In addition, the germanium of the central portion 29 is doped during growth and not through ion implantation, thereby also contributing to it having a good crystalline quality, and therefore contributing to reducing dark current. It may exhibit phosphorus doping of the order of 10¹⁸ to 10²⁰ cm⁻³. In addition, the fact that the epitaxially grown germanium is doped during growth and not through ion implantation followed by annealing to rectify crystalline defects makes it possible to reduce the uncontrolled diffusion of dopants (for example phosphorus or arsenic, and preferably phosphorus) into the detection portion 10, and thus to reduce dark current.

The size of the n+-doped central portion 29 in the XY plane depends on the size of the photodiode 1: for a photodiode with a pitch of 5 μm, it may be between around 0.5 and 4 μm (and preferably less than 2 μm), and for a pitch of 10 μm, it may be between around 1 and 9 μm.

Moreover, the photodiode 1 comprises a peripheral intermediate portion 27, made of an alternation of monocrystalline thin layers of silicon-germanium 27.1 and germanium 27.2 (cf. FIG. 1C), and surrounding the n+-doped first region 11 in the main plane, on the first face 22a, and located between and at a non-zero distance from the n+-doped first region 11 and from the p+-doped peripheral lateral portion 25.

The peripheral intermediate portion 27 therefore extends in the −Z direction over a non-zero depth of the detection portion 10 from a plane passing through the first face 22a. It also projects here above this plane in the +Z direction, and is at least laterally in contact with the upper insulating layer 23. It surrounds the n+-doped first region 11 in the XY plane, preferably completely, that is to say continuously, but, as a variant, it may surround it discontinuously.

It is formed of a plurality of monocrystalline thin layers of silicon-germanium 27.1 and germanium 27.2, produced in succession through localized epitaxy in a peripheral intermediate notch 26 formed beforehand in the detection portion 1 (cf. FIG. 2D). It has a non-zero depth in the detection portion 10, from a plane passing through the face 22a, preferably at least equal to that of the n+-doped central portion 29, so as to limit the lateral diffusion of n-type dopants (here phosphorus). By way of example, it has a depth of the order of 200 nm, and a lateral dimension in the XY plane of the order of a micron.

The thin layers 27.1 and 27.2 are monocrystalline. To this end, they have a thickness less than or equal to their critical thickness starting from which mechanical stresses relax in a plastic manner (cf. for example FIG. 1C). Therefore, the peripheral intermediate portion 27 has a good crystalline quality that limits the surface component of dark current. The atomic proportion of silicon in the thin layers 27.1 of SiGe is preferably at least equal to 70%, so as to effectively limit the lateral diffusion of n-type dopants. The thin layers of germanium 27.2 also make it possible to limit mechanical stresses and thus to preserve the crystalline quality of the peripheral intermediate portion 27. Preferably, the peripheral intermediate portion 27 is formed of an integer number of pairs of thin layers 27.1 and 27.2 (when the last thin layer is produced), so as to limit mechanical stresses.

The photodiode 1 furthermore comprises metal contacts 31.1, 31.2 for reverse-biasing it from the side of the first face 22a. A metal contact 31.1 is thus arranged here on and in contact with the central portion 29, and makes it possible to electrically bias the n+-doped first region 11. A metal contact 31.2 is arranged here on and in contact with the peripheral lateral portion 25, and makes it possible to electrically bias the p+-doped second region 12. The metal contacts 31.1, 31.2 are electrically insulated from one another here in the XY plane by the upper insulating layer 23 and by a passivation dielectric layer 30. The photodiode 1 is intended to be reverse-biased, for example by applying a negative electrical potential to the p+-doped peripheral lateral portion 25 and by grounding the n+-doped first region 11.

In general, by way of illustration, the photodiode 1 may have dimensions in the XY plane of between around 1 μm and 100 μm. The thickness of the p+-doped second region 12 may be between around 20 nm and 500 nm. The thickness of the intrinsic region 13 may be between around 0.7 μm and 2.5 μm when the photodiode 1 is intended to detect light radiation in the SWIR range or in the near-infrared range (NIR). The zone 11.1 of the n+-doped first region 11 may have a depth of between around 10 nm and 600 nm. The dielectric layers 23 and 30 may together have a thickness that allows the entirety of the upper face of the photodiode 1 to be covered and that is, for example, between around 10 nm and 600 nm, and the thickness of the lower insulating layer 21 may be between around 50 nm and 1 μm.

The photodiode 1 thus has a lower dark current due to the presence of the peripheral intermediate portion 27 based on monocrystalline SiGe and Ge, which limits the lateral diffusion of n-type dopants into the XY plane from the n+-doped first region 11. In addition, the fact that the n+-doped first region 11 is advantageously formed in particular of the central portion 29 made of germanium that is grown epitaxially from the detection portion 10 and that is n+-doped during growth improves the crystalline quality of this region (no mismatch in the lattice parameter between the material of the detection portion 10 and that of the n+-doped central portion 29), and dark current is then limited. Ultimately, the uncontrolled diffusion of n-type dopants is also limited, thereby further contributing to reducing dark current.

It should be noted that comparative tests were performed in order to compare the crystalline quality of a central portion made of n-type doped germanium doped through ion implantation and that of the central portion 29 made of n-type doped germanium doped during growth. For this purpose, Raman spectra were obtained corresponding to the evolution of the light intensity of a laser signal with a wavelength of 532 nm diffused by each central portion. In the first case, the central portion made of germanium is doped through phosphorus ion implantation at a dose 3×10¹⁵ cm⁻² at 40 keV followed by rapid thermal annealing (RTA) at 600° C. for 60 s under nitrogen. The Raman spectrum shows a position of the diffusion peak at 297.00 cm⁻¹ and a full width at half maximum of 5.97 cm⁻¹. By contrast, in the second case, the central portion made of germanium is doped during growth and is not followed by annealing. The Raman spectrum indicates that the diffusion peak is located at 300.56 cm⁻¹ with a full width at half maximum of 3.15 cm⁻¹.

The comparison of the full width at half maximum values shows that germanium doped during growth has a very good crystalline quality compared with that of germanium doped through ion implantation. In addition, the comparison of the values of the position of the peak shows that germanium doped through ion implantation followed by annealing exhibits very high stress deformation, in contrast to germanium that is doped in situ, this stress deformation having an unfavourable impact on the performance of the photodiode 1 in that this causes a drop in the bandgap energy of the germanium, this contributing to increasing dark current. The photodiode 1 with the central portion 29 made of germanium doped during growth therefore has a lower dark current and therefore better performance in comparison with the case of germanium doped through ion implantation.

FIGS. 2A to 21 are schematic and partial, cross-sectional views of various steps of a process for fabricating a photodiode according to the example of FIGS. 1A and 1B, comprising the peripheral intermediate portion 27 based on monocrystalline SiGe and Ge. In this example, the n+-doped first region 11 is produced from the central portion 29 made of germanium that is grown epitaxially and n+-doped during growth.

In this example, the photodiodes 1 are made of germanium and comprise a PIN junction, and are designed to detect infrared radiation in the SWIR range. The photodiodes 1 are planar and passivated, and are reverse-biased from the side of the first face 22a, and here by way a control chip 40 hybridized with the matrix-array of photodiodes 1.

With reference to FIG. 2A, a first semiconductor sublayer 22.1 of monocrystalline germanium is produced. The first semiconductor sublayer 22.1 is attached to a support layer 20, here made of silicon, by way of a lower insulating layer 21, here made of a silicon oxide. This stack takes the form of a GeOI substrate (GeOI standing for germanium-on-insulator). This stack is preferably produced by way of the process described in the publication by Reboud et al. entitled Structural and optical properties of 200 mm germanium-on-insulator (GeOI) substrates for silicon photonics applications, Proc. SPIE 9367, Silicon Photonics X, 936714 (Feb. 27, 2015). Such a process has the advantage of producing a semiconductor sublayer 22.1 of germanium having a complete absence or a low rate of structural defects such as dislocations. The germanium may be not intentionally doped or be doped, for example p-type doped. The semiconductor sublayer 22.1 may have a thickness of between around 100 nm and 600 nm, and for example equal to around 300 nm, and may be covered with a protective layer (not shown) made of a silicon oxide. The lower insulating layer 21 (BOX, for Buried Oxide) may have a thickness of between 50 nm and 1 μm, for example of between 100 nm and 500 nm, and advantageously provides an anti-reflection function. As a variant, the initial structure may be of the type Ge/Si formed of a first semiconductor sublayer 22.1 of germanium grown epitaxially from the support layer 20 made of silicon, or bonded to the support layer 20.

The first sublayer 22.1 made of p+-doped germanium is then doped through ion implantation of a dopant such as boron or gallium, when the first sublayer 22.1 was initially made of intrinsic germanium. The protective layer, where applicable, has been removed beforehand by surface cleaning, and the first sublayer 22.1 of germanium may be coated with a pre-implantation oxide layer (not shown) of a thickness of a few tens of nanometres, for example equal to 20 nm.

The sublayer 22.1 of germanium then has a dopant level of between around 10¹⁸ and 10¹⁹ at/cm³. The dopant may then be diffusion-annealed under nitrogen for a few minutes to a few hours, for example 1 h, at a temperature that may be between 600° C. and 800° C., for example equal to 800° C. This annealing might not be performed when the sublayer 22.1 was doped during growth. Another way of fabricating this p+-doped layer 22.1 is by epitaxially growing a layer of germanium doped with boron in situ between around 10¹⁸ and 10¹⁹ at/cm³ on a sublayer of intrinsic germanium. This epitaxial growth may be carried out at between 400 and 800° C., but preferably at 400° C.

A second semiconductor sublayer 22.2 of germanium is produced through epitaxy from the first sublayer 22.1. The two sublayers 22.1, 22.2 are intended to form the coplanar detection portions 10 made of germanium of the matrix-array of photodiodes 1. The second sublayer 22.2 is formed through epitaxy, for example through chemical vapour deposition (CVD), and preferably through reduced pressure chemical vapour deposition (RPCVD) or through any other epitaxy technique. Annealing operations may be performed in order to reduce the dislocation rate in the sublayer 22.2. The pre-implementation oxide layer, where appropriate, will have been removed beforehand by surface cleaning. The second sublayer 22.2 of germanium is intrinsic here, that is to say not intentionally doped, insofar as it is desired to produce a PIN junction. It is intended to form the light absorption zone of the photodiodes 1. Its thickness depends on the wavelength range of the light radiation to be detected in the case of a photodiode 1. In the context of SWIR photodiodes, the sublayer 22.2 of intrinsic germanium has a thickness for example of between 0.5 μm and 3 μm, preferably equal to 1 μm.

An upper insulating layer 23 is then deposited so as to continuously cover the upper face of the second sublayer 22.2, that is to say so as to cover the detection portions 10 of the photodiodes 1. The upper insulating layer 23 is made of a dielectric material, for example a silicon oxide, a silicon nitride or a silicon oxynitride. The upper face of the second sublayer 22.2 may have been cleaned beforehand. The upper insulating layer 23 may have a thickness of between 10 nm and 600 nm.

With reference to FIG. 2B, a peripheral lateral trench 24 is produced, which is intended to pixelate the photodiodes 1 and to contribute to electrically reverse-biasing them (by way of the peripheral lateral portions 25 that are then produced) from the first face 22a. Localized etching of the upper insulating layer 23, of the sublayer 22.2 of intrinsic germanium and of the sublayer 22.1 of p+-doped germanium is thus performed through photolithography and etching until they open out here onto the upper face of the lower insulating layer 21 (but the lateral trenches 24 may open out onto the sublayer 22.1 without passing through it). Each lateral trench 24 thus preferably extends continuously around a photodiode 1. This thus gives a plurality of detection portions 10 that are separated from one another by a continuous lateral trench 24. These are preferably obtained using an anisotropic etching technique, so as to obtain a lateral edge 10c that is substantially vertical along the Z axis. The lateral trenches 24 have a transverse dimension (width) in the XY plane that may be between 300 nm and 2 μm, for example equal to 1 μm. The detection portions 10 may thus have a circular, oval, polygonal, for example square, shape in the XY plane, or any other shape.

With reference to FIG. 2C, the p-type doped peripheral lateral portions 25 are then produced. For this purpose, a doped semiconductor material is deposited so as to fill each lateral trench 24. The semiconductor material is preferably a material based on silicon, for example amorphous silicon, polycrystalline silicon, silicon-germanium, or even amorphous germanium, deposited through epitaxy at a temperature of between 500° C. and 700° C., for example. The semiconductor material is p+-doped with boron or gallium, at a dopant concentration of the order of around 10¹⁹ to 10²⁰ at/cm³. The doped semiconductor material thus comes into contact with the lateral edge 10c via the lateral trench 24. A chemical-mechanical polishing (CMP) step is then performed, with stopping on the upper face of the upper insulating layer 23, in order to eliminate the excess semiconductor material and planarize the upper face formed by the upper insulating layer 23 and the semiconductor material of the peripheral lateral portion 25. This thus gives a p+-doped peripheral lateral portion 25 in each lateral trench 24. Annealing is then performed in order to passivate the lateral edge 10c of the detection portion 10. This annealing ensures the diffusion of the p-type dopants from the peripheral lateral portion 25 into the germanium of the detection portion 10, thus forming a p+-doped lateral region 14. This annealing also ensures inter-diffusion of the silicon from the peripheral lateral portion 25 into the detection portion 10, thus forming a lateral zone 15 of SiGe that ensures a gap opening. This annealing may be performed under nitrogen at a temperature of between for example 600° C. and 750° C., for a duration ranging for example from 10 min to 60 min.

With reference to FIG. 2D, a peripheral intermediate notch 26 is then produced, this being intended to subsequently form the peripheral intermediate portion 27 based on monocrystalline SiGe and Ge. For this purpose, a dielectric layer is first deposited so as to cover the upper surface of the peripheral lateral portions 25 (this thus increases the thickness of the upper insulating layer 23, which thus covers the peripheral lateral portions 25). Next, the peripheral intermediate notch 26 is produced, through photolithography and etching, within the upper insulating layer 23 and the detection portion 10, facing a peripheral zone located at a distance in the XY plane from the peripheral lateral portions 25, on the one hand, and from a central zone intended to form the central notch 28, on the other hand. It may have a width of between 0.3 μm and 5 μm, for example, and be equal to 1 μm, for example. The peripheral intermediate notch 26 has a non-zero depth within the detection portion 10, for example of a few hundred nanometres. Preferably, its depth with respect to the plane of the first face 22a is at least equal to that of the central portion 29 of n+-doped germanium, so as to effectively limit the lateral diffusion of dopants from the central portion 29.

With reference to FIG. 2E, the peripheral intermediate portion 27 based on an alternation of monocrystalline thin layers of SiGe and Ge is then produced. These thin layers are produced through localized epitaxy from the free surface of the detection portion 10, that is to say from the surface that is freed of germanium of the detection portion 10 in the peripheral intermediate notch 26. Multiple periods of pairs formed of a monocrystalline thin layer of SiGe and a monocrystalline thin layer of Ge are thus produced through epitaxy. The number of periods depends on the depth of the peripheral intermediate notch 26, which itself depends on the depth here of the central portion 29 of n+-doped Ge. It may be between 2 and 100 nm, or even more. As indicated above, the thin layers are said to be monocrystalline in that they do not have structural defects such as dislocations. To this end, they have a thickness less than the critical thickness starting from which mechanical stresses relax in a plastic manner (thereby generating structural defects), such that the peripheral intermediate portion 27 has a very good crystalline quality, thus reducing the surface component of dark current. The thickness thereof is therefore less than or equal to around 4 nm, and may be of the order of around 3 mm. The material of these monocrystalline thin layers is not intentionally n-type doped. By contrast, it may be intrinsic (not intentionally doped), or may even be p-type doped (for example like the material of the intermediate region 13). The peripheral intermediate portion 27 may thus limit the lateral diffusion of n-type dopants from the n+-doped first region 11, thus reducing the surface component of dark current. Preferably, each thin layer of SiGe preferably comprises an atomic proportion of at least 70% silicon, so as to effectively limit the lateral diffusion of dopants from the n+-doped first region 11. Moreover, the peripheral intermediate portion 27 may be surrounded by an inter-diffusion zone formed of SiGe (dashed line from FIG. 2G) located in a detection portion 10, which ensures a gap opening that further reduces dark current. This inter-diffusion zone may be formed when producing the n+-doped central portion 29 and the n+-doped first region 11.

With reference to FIG. 2F, a central notch 28 is then produced, this being intended to subsequently form the central portion 29 made of germanium that is grown epitaxially and is n+-doped during growth. For this purpose, a dielectric layer is first deposited so as to cover the upper surface of the peripheral intermediate portion 27 (this thus increases the thickness of the upper insulating layer 23). Next, the central notch 28 is produced, through photolithography and etching, within the upper insulating layer 23 and the detection portion 10, facing a central zone located in the centre of the detection portion 10, surrounded in the XY plane by the peripheral intermediate portion 27. It may have a width of between 0.3 μm and 5 μm, for example, equal to 2 μm, for example. The central notch 28 has a non-zero depth within the detection portion 10, preferably at most equal to that of the peripheral intermediate portion 27 (with respect to the plane of the first face 22a), so as to effectively limit the lateral diffusion of dopants from the n+-doped central portion 29.

With reference to FIG. 2G, the central portion 29 made of n+-doped germanium is then produced through localized epitaxy from the free surface of the detection portion 10 located in the central notch 28. The central portion 29 may be grown epitaxially through reduced pressure chemical vapour deposition (RPCVD), for example at a temperature of between 400° C. and 800° C. The central portion 29 is made of a material identical to that of the detection portion 10, therefore here of germanium. It is additionally n-type doped during growth (and therefore not through ion implantation), for example with phosphorus or arsenic, so as to exhibit doping of the order of 10′⁸ to 10²⁰ cm′. The central portion 29 therefore fills a thickness such that it fills the space defined by the central notch 28, and may project beyond the upper insulating layer 23. A chemical-mechanical polishing (CMP) step is then performed, with stopping on the upper face of the upper insulating layer 23, in order to eliminate the excess germanium and planarize the upper face formed by the upper insulating layer 23 and the germanium of the central portion 29. The depth of the central portion 29 in the detection portion 10 may be between around 50 nm and 1 μm, and may be of the order of 200 nm. It should be noted that, prior to the step of epitaxially growing the n+-doped germanium, the surface free of germanium of the central notch 28 may be cleaned with hydrofluoric acid followed by annealing under H2 so as to avoid residual contamination with oxygen, carbon and fluorine. Moreover, activation annealing of the dopants may or may not be performed depending on the epitaxy temperature of the central portion 29. Thus, by way of example, in the case of low-temperature epitaxy (for example 400° C.), provision is made for an activation step with for example rapid thermal annealing (RTA) between 500° C. and 600° C. for 10 to 30 sec. In the case of epitaxy above 600° C., it is no longer necessary to add this annealing step since the n-type dopants are already activated.

This thus gives a central portion 29 made of n+-doped germanium having a good crystalline quality, thereby contributing to reducing dark current. It should also be noted that n-type dopants of the central portion 29, specifically here phosphorus or arsenic, diffuse into the germanium of the detection portion 10 in this epitaxy step. This therefore gives an n+-doped first region 11 formed firstly of the central portion 29 made of germanium that is grown epitaxially and n+-doped in situ, and secondly of the n+-doped adjacent zone 11.1. It should be noted lastly that the lateral diffusion in the XY plane of these dopants is greatly limited by the presence of the peripheral intermediate portion 27 made of monocrystalline SiGe and Ge, this being reflected by a reduction in the surface component of dark current.

With reference to FIG. 2H, the central metal contact 31.1 and lateral metal contact 31.2 are produced. For this purpose, a passivation dielectric layer 30 is first deposited so as to cover the central portion 29. The dielectric layer 30 may be deposited at 400° C. and be made of a dielectric material such as a silicon oxide, silicon nitride or silicon oxynitride, an aluminium oxide or aluminium nitride, a hafnium oxide, inter alia. It may have a thickness of for example between 200 nm and 1000 nm. A CMP planarization step is then performed. Through-openings are then produced through the dielectric layers 23, 30 so as to open out onto an upper surface of the central portion 29 and onto an upper surface of the peripheral intermediate portion 27. Finally, the central metal contact 31.1 and lateral metal contact 31.2 are produced. An attachment thin layer formed of a Ti/TiN/Cu stack is deposited here into the through-openings through chemical vapour deposition, and the empty space is filled with copper deposited by electrolysis. A CMP planarization step is then performed with stopping on the oxide of the passivation dielectric layer 30. The passivation dielectric layer 30 and the metal contacts 31.1 and 31.2 together have one and the same planar upper face.

With reference to FIG. 2I, the optoelectronic stack thus obtained is hybridized on a control chip 40. The connection face of the control chip 40 may thus be coated with an insulating layer 41, made of a dielectric material, through which metal contacts 42 pass. The matrix-array of photodiodes 1 and the control chip 40 are thus assembled by hybrid molecular adhesion, though contact between the faces formed by the metal contacts and the insulating layers. Bonding annealing may be performed so as to increase the surface bonding energy between the two faces in contact. The support layer 20 is then removed, for example by abrasion (grinding), so as to expose the lower insulating layer 21. This thus forms the reception face for the light radiation to be detected, and advantageously provides an anti-reflection function.

The fabrication process thus makes it possible to obtain one or more passivated photodiodes 1, each comprising a peripheral intermediate portion 27 located on the first face 22a and surrounding the n+-doped first region 11, thus making it possible to limit the lateral diffusion of n-type dopants from the n+-doped first region 11, and therefore to reduce the surface component of dark current. The silicon in the portion 27 has a high bandgap energy, thereby contributing to reducing surface dark current. In addition, the n+-doped first region 11 is advantageously formed here in particular from the central portion 29 made of germanium that is grown epitaxially and n+-doped in situ. This central portion 29 therefore has a very good crystalline quality, thereby further reducing dark current, and the uncontrolled diffusion of n-type dopants is also limited. This thus produces one or more photodiodes 1 having improved performance.

According to one variant embodiment, the n+-doped central portion 29 may be made of a crystalline material different from that of the detection portion 10. It may thus be an n+-doped crystalline semiconductor material that has a natural lattice parameter that is identical to within 1%, and preferably to within 0.5%, to that of the crystalline semiconductor material of the detection portion 10, here germanium, and has a bandgap energy greater by at least 0.5 eV than that of the crystalline semiconductor material of the detection portion 10 (germanium). The central portion 29 may thus be made of a binary or tertiary III-V compound, such as GaAs, AlAs, GaAlAs, GaInP, inter alia. The lack of a mismatch in the lattice parameter between the crystalline material of the central portion 29 and that of the detection portion 10 makes it possible to avoid structural defects (dislocations, etc.) that might worsen the performance of the photodiode 1. In addition, the fact that the bandgap energy is greater than that of the germanium of the detection portion 10 makes it possible to reduce the dark current of the photodiode 1, on the one hand, and to reduce the sensitivity of the photodiode 1 to any defects that are present close to the notch 28 in which the central portion 29 is located.

One example of such a central portion 29 is described in patent application FR2101290 filed on Nov. 2, 2021. It may be produced through RPCVD epitaxy or through molecular beam epitaxy (MBE). Moreover, the central portion 29 is also n-type doped here during growth. By way of example, the central portion 29 is made of AIAs or of GaAs (stoichiometric compounds, that is to say that the proportion of the two elements is identical, for which the natural lattice parameter is 5.6605 Å for AIAs and 5.653 Å for GaAs, this corresponding, respectively, to a discrepancy of 0.044% and 0.088% with the natural lattice parameter of 5.658 Å for germanium. In addition, the bandgap energy is 2.12 eV for AIAs and 1.424 eV for GaAs, this being far greater than the 0.67 eV for germanium. Other semiconductor compounds, for example ternary ones, may also be suitable, such as for example GaAlAs and GaInP depending on the proportions of the various chemical elements.

According to one variant embodiment, the central portion 29 is not doped during growth (or through ion implantation), but its material is unintentionally doped during the epitaxy. It is then n+-doped a second time, through the diffusion of n-type dopants from an n+-doped upper portion 32 forming a dopant reservoir. One example of such an upper portion 32 is also described in patent application FR2101290 filed on Nov. 2, 2021. In this variant, the central portion 29 may be made of germanium or of a binary or ternary III-V compound, such as GaAs, AlAs, GaAlAs, GaInP, inter alia, grown epitaxially from the crystalline material of the detection portion 10.

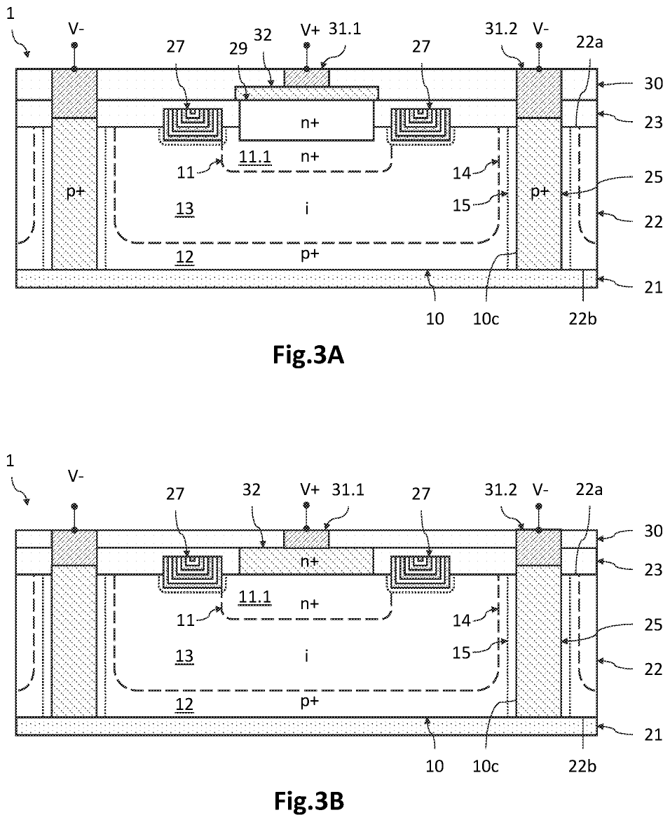

In this regard, FIG. 3A is a schematic and partial, cross-sectional view of a planar photodiode 1 according to one such variant embodiment. The photodiode 1 is similar to that from FIG. 1A, and differs therefrom essentially in that it comprises an upper portion 32, which rests on and in contact with the central portion 29. It is spaced from the peripheral lateral portion 25 and from the metal contacts 31.2 in the XY plane by a non-zero distance. This lateral space is filled here by the passivation dielectric layer 30. The upper portion 32 is made of an n+-doped semiconductor material, with dopants able to n+-dope the central portion 29 and a zone 11.1 of the detection portion so as to form the n+-doped first region 11, n+-doped here with phosphorus or arsenic. The upper portion 32 is thus a dopant reservoir containing dopants intended to diffuse, upon diffusion annealing, through the central portion 29 so as to form the n+-doped first region 11. It is preferably produced from polycrystalline silicon, but other polycrystalline materials may of course be used.

According to another variant embodiment, the photodiode 1 does not comprise a central portion 29 grown epitaxially from the germanium of the detection portion 10 in a central notch 28. The detection portion 10 therefore does not comprise a central notch 28, but only an intermediate peripheral notch in which the peripheral intermediate portion 27 based on monocrystalline SiGe and Ge is located. The n+-doped first region 11 is then a zone 11.1 of the detection portion 10 that extends from the first face 22a.

In this regard, FIG. 3B is a schematic and partial, cross-sectional view of a planar photodiode according to one such variant embodiment. The photodiode 1 is similar to that from FIG. 3A, and differs therefrom essentially in that it does not comprise a central portion 29, and in that the upper portion 32 rests on and in contact with the detection portion 10. It is spaced from the peripheral lateral portion 25 and from the metal contacts 31.2 in the XY plane by a non-zero distance. This lateral space is filled here by the upper insulating layer 23. The upper portion 32 is made of an n+-doped semiconductor material, with dopants able to n+-dope a zone 11.1 of the detection portion 10 so as to form the n+-doped first region 11, n+-doped here with phosphorus or arsenic. In this case too, the upper portion 32 is thus a dopant reservoir containing dopants intended to diffuse, upon diffusion annealing, through the central portion 29 so as to form the n+-doped first region 11. It is preferably produced from polycrystalline silicon, but other polycrystalline materials may of course be used.

Particular embodiments have just been described. Various variants and modifications will seem obvious to anyone skilled in the art.

1. A planar photodiode, comprising:
a main layer having a first face and a second face that are opposite one another and parallel to a main plane, made of a first crystalline semiconductor material based on germanium, comprising a detection portion formed of:
an n-type doped first region flush with the first face, intended to be electrically biased;
a p-type doped second region flush with the second face;
an intermediate region, located between the doped first region and the doped second region and surrounding the doped first region in the main plane;
a peripheral lateral portion, made of a p-type doped second semiconductor material, surrounding the detection portion in the main plane, and coming into contact with the doped second region, and intended to be electrically biased;
a peripheral intermediate portion, made of an alternation of monocrystalline thin layers of silicon-germanium and germanium, located in contact with the detection portion on the first face, and extending between and at a non-zero distance from the doped first region and from the peripheral lateral portion so as to surround the doped first region in the main plane.

2. The planar photodiode according to claim 1, wherein the monocrystalline thin layers of silicon-germanium comprise an atomic proportion of silicon at least equal to 70%.

3. The planar photodiode according to claim 1, wherein the monocrystalline thin layers of silicon-germanium and germanium each have a thickness less than or equal to 4 nm.

4. The planar photodiode according to claim 1, wherein the peripheral intermediate portion extends into a notch, called peripheral intermediate notch, of the detection portion located on the first face.

5. The planar photodiode according to claim 1, comprising a central portion made of an n-type doped second crystalline semiconductor material, identical to the first crystalline semiconductor material, located in contact with the detection portion on the first face, and contributing to forming the doped first region.

6. The planar photodiode according to claim 5, comprising an upper insulating layer covering the detection portion on the first face and the peripheral intermediate portion, and laterally surrounding part of the central portion that projects beyond the detection portion.

7. The planar photodiode according to claim 5, comprising an upper portion located on and in contact with the central portion, made of an n-type doped crystalline semiconductor material.

8. The planar photodiode according to claim 1, comprising an upper portion located on and in contact with the detection portion, made of an n-type doped crystalline semiconductor material.

9. The planar photodiode according to claim 1, comprising metal contacts intended to electrically bias the photodiode, including at least one central metal contact electrically biasing the doped first region and at least one lateral metal contact coming into contact with the peripheral lateral portion.

10. The planar photodiode according to claim 1, wherein the detection portion is made of germanium, and the peripheral lateral portion is based on silicon.

11. A process for fabricating at least one photodiode according to claim 1, comprising the following steps:
producing a stack comprising a first sublayer intended to form the second region and a second sublayer intended to form the intermediate region, both covered by an upper insulating layer;
producing the peripheral lateral portion through the stack so as to open out onto the first sublayer;
producing a peripheral intermediate notch in the detection portion through the upper insulating layer and part of the second sublayer, surrounding a zone intended to form the doped first region;
producing the peripheral intermediate portion, in the peripheral intermediate notch, through epitaxy from the second sublayer.

12. The fabrication process according to claim 11, comprising the following step, following the production of the peripheral intermediate portion:
producing a central notch in the detection portion through the upper insulating layer, surrounded, in the main plane, by the peripheral intermediate portion;
producing a central portion made of a second crystalline semiconductor material identical to the first crystalline semiconductor material, in the central notch, through epitaxy from the second sublayer, and n-type doping the central portion during growth, the central portion thus contributing to forming the doped first region.

13. The fabrication process according to claim 12, wherein the central notch has a depth with respect to a plane passing through the first face at most equal to that of the peripheral intermediate notch.

14. The fabrication process according to claim 11, comprising the following steps:
producing a central notch in the detection portion through the upper insulating layer and part of the second sublayer, surrounded, in the main plane, by the peripheral intermediate portion;
producing a central portion made of a second crystalline semiconductor material identical to the first crystalline semiconductor material, in the central notch, through epitaxy from the second sublayer, the second crystalline semiconductor material being not intentionally doped;
producing an upper portion on and in contact with the central portion, made of an n-type doped crystalline semiconductor material;
diffusion annealing, such that the dopants contained in the upper portion diffuse through the central portion and into part of the second sublayer so as to contribute to forming the doped first region.

15. The fabrication process according to claim 11, comprising the following steps:
producing an upper portion on and in contact with the detection portion, made of an n-type doped crystalline semiconductor material;
diffusion annealing, such that the dopants contained in the upper portion diffuse into part of the second sublayer so as to form the doped first region.
